(19) United States
(12) Patent Application Publication
(10) Pub. No.: US 2024/0363699 A1
(43) Pub. Date: Oct. 31, 2024

(54) SEMICONDUCTOR DEVICE HAVING A TRENCH STRUCTURE WITH LOWER, UPPER, AND INTERMEDIARY SECTIONS AND METHOD OF PRODUCING THE SEMICONDUCTOR DEVICE

(71) Applicant: Infineon Technologies Austria AG, Villach (AT)

(72) Inventors: Annett Winzer, Dresden (DE); Lars Mueller-Meskamp, Dresden (DE); Tom Peterhaensel, Dresden (DE); Fabian Geisenhof, München (DE); Torsten Helm, Bannewitz (DE); Dirk Manger, Dresden (DE)

(21) Appl. No.: 18/140,253

(22) Filed: Apr. 27, 2023

(51) Int. Cl. H01L 29/40

(52) U.S. Cl. CPC H01L 29/407; H01L 29/401

(57) ABSTRACT

A semiconductor device includes: a semiconductor substrate having a first main surface and a second main surface opposite the first main surface; and a trench structure extending into the semiconductor substrate from the first main surface. The trench structure includes: an upper section extending into the semiconductor substrate from the first main surface; a lower section at an opposite end of the trench structure as the upper section; a first intermediary section between the upper section and the lower section; a field plate in the upper section and dielectrically insulated from the semiconductor substrate; and a first dielectric material completely filling the lower section. The lower section, the upper section, and the first intermediary section have different geometries and/or different dielectric materials. Methods of producing the semiconductor device are also described.

### BACKGROUND

For integrated high voltage devices (e.g., breakdown voltage greater than 50V) such as power diodes and LDMOS (laterally-diffused metal-oxide semiconductor) transistors, optimization of device parameters such as ruggedness, low on-state resistance, high breakdown voltage, etc. requires careful control of the electric potential and fields inside the device for all operating conditions. Conventional devices include field guiding elements such as field plates above the semiconductor substrate, graded implant schemes, p/n compensation structures, and the like. However, each of these techniques has limited influence on the electric potential and field distribution deeper in the semiconductor substrate.

### SUMMARY

According to an embodiment of a semiconductor device, the semiconductor device comprises: a semiconductor substrate having a first main surface and a second main surface opposite the first main surface; and a trench structure extending into the semiconductor substrate from the first main surface, wherein the trench structure comprises: an upper section extending into the semiconductor substrate from the first main surface; a lower section at an opposite end of the trench structure as the upper section; a first intermediary section between the upper section and the lower section; a field plate in the upper section and dielectrically insulated from the semiconductor substrate; and a first dielectric material completely filling the lower section, wherein the lower section, the upper section, and the first intermediary section have different geometries and/or different dielectric materials.

According to an embodiment of a method of producing a semiconductor device, the method comprises: forming, by an etch process, a trench structure that extends into a semiconductor substrate from a first main surface of the semiconductor substrate; controlling a plurality of in situ phases of the etch process such that the trench structure has a plurality of sections with different geometries, including an upper section that extends into the semiconductor substrate from the first main surface, a first intermediary section below the upper section, and a lower section below the first intermediary section and at an opposite end of the trench structure as the upper section; forming a first dielectric material that completely fills the lower section; and forming a field plate in the upper section and that is dielectrically insulated from the semiconductor substrate.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a cross-sectional view of part of a semiconductor device having a field plate trench structure the bottom part of which is completely filled by a dielectric material.

FIG. 2A illustrates an electric field in the semiconductor that arises at the bottom part of the trench structure of FIG. 1 when a relatively high potential (e.g., +700V) is applied to a metallized backside of the device and a relatively low potential (e.g., 0V) is applied to the field plate.

FIG. 2B illustrates the electric field in the semiconductor under the same biasing conditions as FIG. 2A, but instead with the field plate extending into the lower section of the trench structure.

FIGS. 3A and 3B illustrate respective cross-sectional views during different stages of producing the trench structure, according to an embodiment.

FIGS. 4A through 4D illustrate respective cross-sectional views during an in situ phase of an etch process used to form part of the trench structure, according to an embodiment.

FIG. 4E illustrates the trench structure upon completion of the etch process and prior to trench dielectric and field plate formation.

FIGS. 5A and 5B illustrate respective cross-sectional views during different stages of producing the trench structure, according to another embodiment.

FIGS. 6A through 6E illustrate respective cross-sectional views during in situ phases of an etch process that forms the trench structure shown in FIGS. 5A and 5B.

FIGS. 7A and 7B illustrate respective cross-sectional views during different stages of producing the trench structure, according to another embodiment.

### DETAILED DESCRIPTION

The embodiments described provide a trench structure formed in a semiconductor substrate of a semiconductor device. The trench structure includes lower, upper, and one or more intermediary sections having different geometries and/or different dielectric materials. The expression “different geometries” as used herein means different shapes and/or forms of a surface or solid. For example, the lower, upper, and one or more intermediary sections of the trench structure may have a different average, top, and/or bottom width/critical dimension (CD), depth, sidewall taper (form, shape, angle, etc.), etc.

A field plate in at least the upper section of the trench structure may be used to modulate the electrical field distribution into a depth of the semiconductor substrate. A trench etch process used to form the trench structure may be controlled to size the length and/or shape of the trench structure conductive fill material that forms the field plate. Etching of a distinctive trench structure geometry combined with a subsequent trench structure fill process allows for a realization of a defined field plate length and/or shape. The trench structure profile/geometry is etched in-situ with various segments of different widths/CDs and segment lengths. The trench structure etch process may be used for distinctive void tuning within the trench structure fill, to control the mechanical wafer stress and fracture strength.

Described next, with reference to the figures, are embodiments of the trench structure and methods of producing the trench structure.

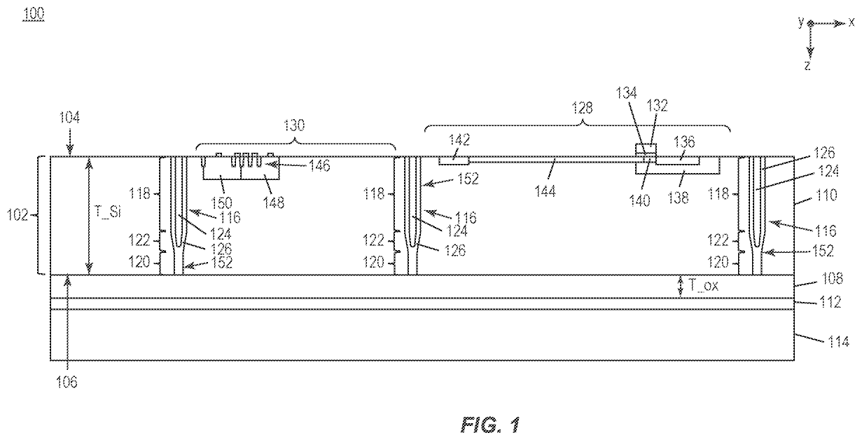

FIG. 1 illustrates a cross-sectional view of part of a semiconductor device 100. The device 100 includes a semiconductor substrate 102 having a first main (front) surface 104 and a second main (back) surface 106 opposite the front surface 104. The semiconductor substrate 102 comprises one or more semiconductor materials that may be used to form semiconductor devices such as, e.g., power diodes, power MOSFETs (metal-oxide-semiconductor field-effect transistors), LDMOS transistors, lateral IGBTs (insulated gate bipolar transistors), HEMTs (high-electron mobility transistors), JFETs (junction FETs), gate driver circuitry, logic circuitry, etc. For example, the semiconductor substrate 102 may comprise Si, silicon carbide (SIC), germanium (Ge), silicon germanium (SiGe), gallium nitride (GaN), gallium arsenide (GaAs), and the like. The semiconductor substrate 100 may include one or more epitaxial layers.

In one embodiment, the back surface 106 of the semiconductor substrate 102 is not electrically insulated. For example, an electrode (not shown) may be formed at the back surface 106 of the semiconductor substrate 102.

In another embodiment, the semiconductor substrate 102 is an SOI (silicon-on-insulator) substrate (i.e., Si/oxide/Si). According to this embodiment, a backside dielectric material 108 covers the back surface 106 of a silicon layer 110, making the back surface 106 of the semiconductor substrate 102 electrically insulated. The backside dielectric material 108 that covers the silicon layer 110 may be an oxide having a thickness T_ox in a range of 0.8 μm (microns) to 35 μm, for example.

At least one additional layer 112 such as a barrier layer and/or an adhesion promotion layer may be formed on the dielectric material 108 covering the back surface 106 of the silicon layer 110. For example, the at least one additional layer 112 may include an adhesion promotion layer that comprises any kind of material suitable for providing adhesion between a substrate 114 and the dielectric material 108, e.g. an organic adhesion promoter, any kind of glue, a DAF tape, or the like. One or more barrier layers between the substrate 114 and the silicon layer 110 may increase the dielectric strength of the stack. For example, the at least one additional layer 112 may include one or more metallization layers such as Cu (copper), Al (aluminum), AlCu, etc. formed on the backside dielectric material 108 opposite the silicon layer 110. A substrate 114 such as a die carrier, lead frame, printed circuit board, etc. may be attached to the side of the at least one additional layer 112 opposite the silicon layer 110.

In the case of an SOI implementation for the semiconductor device 100, the thickness T_Si of the silicon layer 110 may be in a range of 10 um to 200 um between the front surface 104 and the electrically insulated back surface 106 of the silicon layer 110. The silicon layer 110 with the electrically insulated back surface 106 may be realized by forming one or more devices such as a power diode, high voltage transistor, a gate driver for a power transistor, etc. in a bulk silicon wafer or in one or more epitaxial layers grown on a bulk silicon wafer, and then grinding the backside of the bulk silicon wafer to the final SOI thickness T_Si. The thinned wafer backside is then covered by the backside dielectric material 108 to yield the electrically insulated back surface 106 of the silicon layer 110. The resulting silicon layer 110 is thicker (e.g., T_Si=10 μm to 200 μm) than typical SOI device layers which usually have a thickness in the nanometer (nm) range. However, the silicon layer 110 instead may be produced by SIMOX (separation by implantation of oxygen), wafer bonding, etc., methods which may include epitaxy, and therefore have a thickness T_Si in the nanometer range. For example, the backside dielectric material 108 may comprise an oxide, e.g. silicon oxide, and/or a nitride, e.g. silicon nitride, deposited on the back surface 106.

Regardless of whether the semiconductor device 100 is an SOI or non-SOI device, the semiconductor device 100 also includes a trench structure 116 that extends into the semiconductor substrate 102 from the front surface 104. The trench structure 116 includes an upper section 118 that extends into the semiconductor substrate 102 from the front surface 104, a lower section 120 at an opposite end of the trench structure 116 as the upper section 118, and a first intermediary section 122 between the upper section 118 and the lower section 120. In the case of an SOI implementation for the semiconductor device 100, the trench structure 116 may extend through the silicon layer 110 from the front surface 104 to the back surface 106 such that the lower section 120 of the trench structure 116 adjoins the backside dielectric material 108 that covers the silicon layer 110.

The trench structure 116 also includes a field plate 124 at least in the upper section 118 and dielectrically insulated from the semiconductor substrate 102. The field plate 124 is made of an electrically conductive material such as doped or undoped polysilicon and/or a metal or metal stack. The trench structure 116 further includes a dielectric material 126 that completely fills the lower section 120 of the trench structure 116. The dielectric material 126 may be SiOx, SIN, HfOx, etc. or a layer stack of two or more of these or similar dielectric materials.

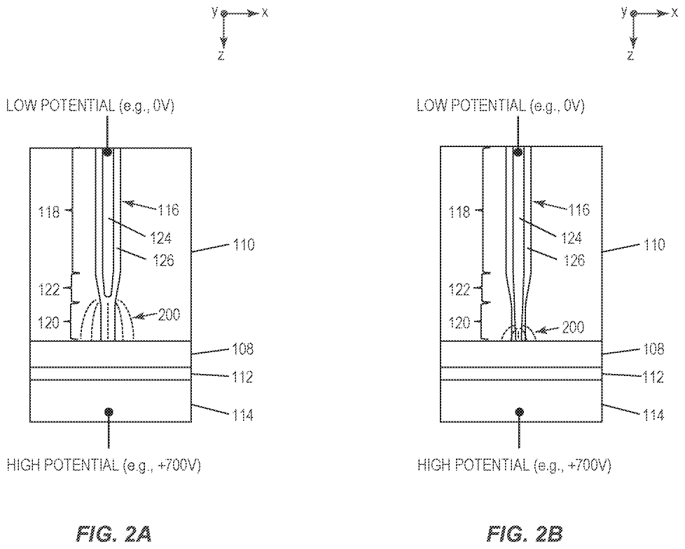

Since the dielectric material 126 completely fills the lower section 120 of the trench structure 116, the field plate 124 terminates before reaching the electrically insulated backside 106 of the silicon layer 110. As indicated in FIG. 2A, a lower-intensity electric field 200 arises at the bottom part of the trench structure 116 in the adjacent parts of the silicon layer 110 and the backside dielectric material 108 when a relatively high potential (e.g., +700V) is applied to the metallized backside 112 and a relatively low potential (e.g., 0V) is applied to the field plate 124. The electric field 200 has a lower intensity because the length of the field plate 124 is decreased and the lower section 120 of the trench structure 116 is completely filled by a dielectric material 126, enabling a higher breakdown voltage at the trench bottom. If, instead, the field plate 124 extended into the lower section 120 of the trench structure 116, e.g., to the backside dielectric material 108, the intensity of the electric field 200 would be much higher as indicated in FIG. 2B, causing impact ionization and other issues that may lead to dielectric degradation and/or breakdown.

Returning to FIG. 1, the lower section 120, the upper section 118, and the first intermediary section 122 of the trench structure 116 have different geometries and/or different dielectric materials. As explained above, this means that the lower section 120, the upper section 118, and the first intermediary section 122 of the trench structure 116 may have different shapes and/or forms of a surface or solid. For example, the lower section 120, the upper section 118, and the first intermediary section 122 of the trench structure 116 may have a different average, top, and/or bottom width/CD, depth, sidewall taper (form, shape, angle, etc.), etc.

Separately or in addition, the same or different dielectric material may be disposed in the lower section 120, the upper section 118, and the first intermediary section 122 of the trench structure 116. In FIG. 1, the same dielectric material 126 is shown separating the field plate 124 from the semiconductor substrate 102 in the upper section 118 and the first intermediary section 122 and completely filling the lower section 120. However, different dielectric materials may be used in the lower section 120, the upper section 118, and/or the first intermediary section 122 of the trench structure 116.

The semiconductor device 100 may have a high voltage region 128 and a low voltage region 130 formed in the semiconductor substrate 102 and laterally spaced apart from one another, e.g., by the trench structure 116. The high voltage region 128 may include isolated high voltage (e.g., greater than 50V or higher) islands and the low voltage region 130 may include isolated low voltage (e.g., less than 40V) islands.

For example, the high voltage region 128 may be part of a high voltage domain comprising one or more low voltage device structures within the high voltage domain and/or the low voltage region 130 may be part of a low voltage domain comprising one or more low voltage device structures within the low voltage domain. The respective low voltage device structures may extend only within the respective voltage domain. The respective low voltage device structures may have a breakdown voltage smaller than a nominal voltage between the low and high voltage domains, e.g., by a factor of at least 2 or at least 5 or at least 10. The respective low voltage device structures may comprise CMOS devices having a breakdown voltage less than 50V. In another example, the high voltage region 128 may be a high side region of a gate driver and the low voltage region 130 may be a low side region of the gate driver.

In FIG. 1, an LDMOS device is formed in the high voltage region 128. The LDMOS device includes a planar gate electrode 132 separated from the front surface 104 of the semiconductor substrate 102 by a gate dielectric 134, a source region 136 disposed in a body region 138 of the opposite conductivity type and which includes a channel region 140 controlled by the gate electrode 132, and a drain region 142 disposed at the same side of the semiconductor substrate 102 as the source region 136 and laterally separated from the channel region 140 by a drift zone 144 of the same conductivity type as the source and drain regions 136, 142. The low voltage region 130 may include logic and/or power device features 146 formed in different voltage islands 148, 150. These are just a few examples of the high and low voltage regions 128, 130 of the semiconductor device 100 and should not be considered limiting.

The trench structure 116 may adjoin the high voltage region 128, adjoin the low voltage region 130, or laterally separate the high and low voltage regions 128, 130 from one another, for example. The field plate 124 included in the trench structure 116 may be electrically connected to a potential applied to a region of the high voltage region 128, a potential applied to a region of the low voltage region 130, a different potential or signal, or may be floating.

In the case of a needle-shaped trench structure, the trench structure 116 has a single curved sidewall 152. In the case of a stripe-shaped trench structure, the trench structure 116 has two opposing sidewalls 152. In FIG. 1, the first intermediary section 122 of the trench structure 116 has tapered sidewalls 152.

The term ‘needle-shaped’ as used herein means a structure that is narrow and long in the depth-wise direction (z direction in FIG. 1) of the semiconductor substrate 102. For example, the trench structure 116 may resemble a needle, column, or spicule in the depth-wise direction of the semiconductor substrate 102. The term ‘stripe-shaped’ as used herein means a structure having a longest linear dimension in a direction (y direction in FIG. 1) transverse to the depth-wise direction of the semiconductor substrate 102.

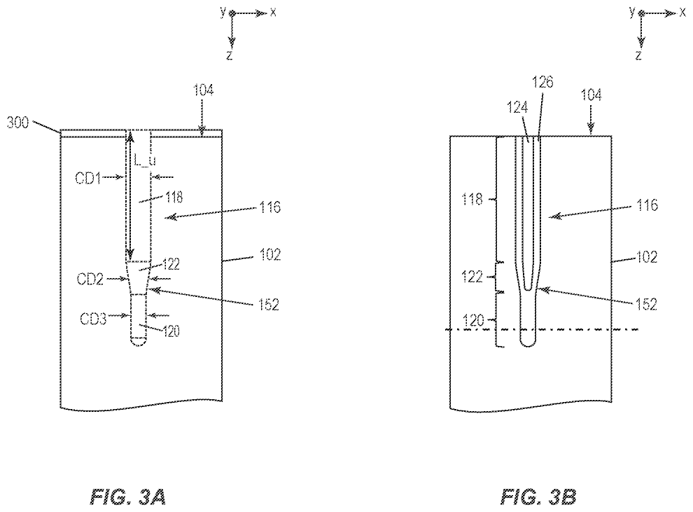

FIGS. 3A and 3B illustrate respective cross-sectional views during different stages of producing the trench structure 116 in one part of the semiconductor substrate 100. FIG. 3A shows a mask 300 on the front surface 104 of the semiconductor substrate 100 and the trench structure 116 after the lower section 120, the upper section 118, and the first intermediary section 122 are etched into the substrate 100 from the front surface 104 but before the field plate 124 and trench dielectric material 126 are formed.

A plurality of in situ phases of an etch process may be controlled such that the lower section 120, the upper section 118, and the first intermediary section 122 of the trench structure 116 have different geometries, with the upper section 118 extending into the semiconductor substrate 102 from the first main surface 104, the first intermediary section 122 being below the upper section 118, and the lower section 120 being below the first intermediary section 122 and at an opposite end of the trench structure 116 as the upper section 118. The same mask 300 may remain on the front surface 104 of the semiconductor substrate 102 during each in situ phase of the etch process.

In FIG. 3A, the first intermediary section 122 of the trench structure 116 adjoins the lower section 122 and has tapered sidewalls 152. According to this embodiment, the average width/critical dimension CD3 of the lower section 120 is less than the average width/critical dimension CD2 of the first intermediary section 122. The average width/critical dimension CD1 of the upper section 118 of the trench structure 116 is greater than the average width/critical dimension CD2 of the first intermediary section 122.

In FIG. 3A, the length ‘L_u’ of the upper section 118 of the trench structure 116 defines the length of the field plate 124 in the z direction. The width/critical dimension CD1 of the upper section 118 determines whether the field plate 124 will have a void (e.g., keyhole void for a large CD, void with Si-bridges for a medium CD, no voids for a small CD) in the upper section 118.

In FIG. 3A, the profile/geometry of the first intermediary section 122 of the trench structure 116 determines the shape of the lower tip/end of the field plate 124 and thus the electrical field behavior in the lower part of the trench structure 116. The first intermediary section 122 allows for a closed polysilicon/metal seamline without voids. A void-free segment of the field plate 124 increases wafer fracture strength.

In FIG. 3A, the profile/geometry of the lower section 120 of the trench structure 116 ensures that the bottom part of the trench structure 116 is completely filled by a dielectric material 126. The lower section 120 is void-free to avoid defects during grinding/backside thinning of the semiconductor substrate 102.

FIG. 3B shows the trench structure 116 after the field plate 124 and trench dielectric material 126 are formed. For example, the same or different dielectric material 126 may be deposited and/or thermally grown so as to line the sidewalls 152 of the upper section 118 and the first intermediary section 122 of the trench structure 116 and completely fill the lower section 120. The field plate 124 is then formed at least in the upper section 118 of the trench structure 116.

The horizontal dashed line in FIG. 3B indicates a target thickness to which the semiconductor substrate 100 is subsequently thinned, e.g., to produce a thin vertical power die (chip) or an SOI die. In one embodiment, the semiconductor substrate 102 is thinned at the back surface 106 (out of view in FIG. 3B) to expose the lower section 120 of the trench structure 116 at the thinned back surface 106 of the substrate 102. The thinned back surface 106 of the substrate 102 may be covered with a dielectric material 108 as shown in FIG. 1, to form an SOI device. As shown in FIG. 3B, the lower section 120 of the trench structure 116 is completely filled by the trench dielectric material 126 to ensure a vertical dielectric separation between the bottom of the field plate 124 and the back surface 106 of the semiconductor substrate 102 post substrate thinning.

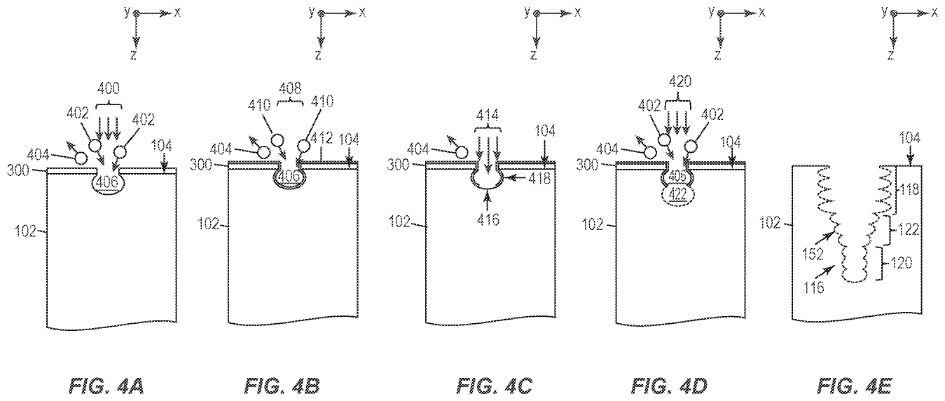

FIGS. 4A through 4D illustrate respective cross-sectional views during an in situ phase of the etch process, according to an embodiment. The in situ phase of the etch process may be controlled such that the average width/critical dimension CD1 of the upper section 118 of the trench structure 116 is different than the average width/critical dimension CD2, CD3 of the trench sections 120, 122 below the upper section 118 of the trench structure 116.

Parameters of the etch process such as temperature, gas flow, pressure, RF power for high density plasma, bias, etc. define the etch profile. RAP (rapid alternating process)-mode etching may be used to control the process parameters and thereby enable etching of different trench section profiles which yields different geometries. For example, a ramp function used during RAP-mode etching may be linear or non-linear and the number of cycles may be chosen to define a step-width of the ramp. RAP-mode etching may be combined with a steady-state dry etching mode where there is no switching between etch and passivation steps.

FIG. 4A illustrates a first sputtering phase 400 of a RAP-mode etching step. During the first sputtering phase 400, an etch gas 402 such as SF₆ reacts with the part of the front surface 104 of the semiconductor substrate 102 exposed by an etch mask 300. A reaction product 404 releases from the semiconductor substrate 102, resulting in a first etched recess 406 in the substrate 102.

FIG. 4B illustrates a polymer passivation deposition phase 408 of the RAP-mode etching step. The polymer passivation deposition phase 408 is performed without bias and yields only a chemical reaction, and involves switching from the etching gases 402 to deposition gases 410. The polymer passivation deposition phase 408 yields a polymer layer 412 that is formed on the etch mask 300 and along the surface of the first recess 406 etched into the semiconductor substrate 102.

FIG. 4C illustrates a second sputtering phase 414 of the RAP-mode etching step. During the second sputtering phase 414, the polymer layer 412 is removed from the bottom 416 of the first recess 406 etched into the semiconductor substrate 102 but remains on the sidewalls 418 of the first etched recess 406.

FIG. 4D illustrates a third sputtering phase 420 of the RAP-mode etching step. During the third sputtering phase 420, an etch gas 402 such as SF₆ reacts with the exposed bottom 416 of the first recess 406 etched into the semiconductor substrate 102. A reaction product 404 releases from the semiconductor substrate 102, resulting in a second recess 422 that is etched into the substrate 102 and self-aligned with the first etched recess 406.

The in situ phase of the etch process illustrated in FIGS. 4B through 4D is repeated as many times as required to form the desired trench structure profile and depth. The ramp function used during the RAP-mode etching steps may be adjusted and the number of cycles may be chosen to define a desired step-width profile for each section 118, 120, 122 of the trench structure 116, e.g., as shown in FIG. 4E. Accordingly, the trench sections 118, 120, 122 may have a different average, top, and/or bottom width/critical dimension, depth, sidewall taper (form, shape, angle, etc.), etc.

For example, as shown in FIG. 4E, the in situ phase of the etch process that forms the first intermediary section 122 of the trench structure 116 may be controlled such that the first intermediary section 122 has tapered sidewalls 152. The in situ phase of the etch process that forms the lower section 120 of the trench structure 116 may be controlled such that the average width/CD of the lower section 120 is less than the average width/CD of the first intermediary section 122 and small enough to ensure that the lower section 120 will be completely filled by a dielectric material 126. The etch mask 300 and any residual polymer material 412 may be removed at the end of the trench etch process, to facilitate formation of the field plate 124 and trench dielectric 126.

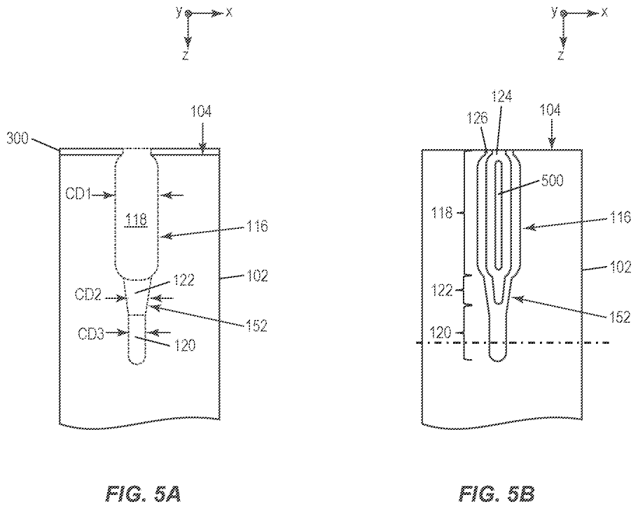

FIGS. 5A and 5B illustrate respective cross-sectional views during different stages of producing the trench structure 116 in one part of the semiconductor substrate 100, according to another embodiment. FIG. 5A shows the trench structure 116 after the lower section 120, the upper section 118, and the first intermediary section 122 are etched into the substrate 100 from the front surface 104 but before the field plate 124 and trench dielectric material 126 are formed. FIG. 5B shows the trench structure 116 after the field plate 124 and trench dielectric material 126 are formed.

The embodiment illustrated in FIGS. 5A and 5B is similar to the embodiment illustrated in FIGS. 3A and 3B. The in situ phases of the etch process used to form the trench structure 116 shown in FIGS. 5A and 5B are controlled such that the field plate 124 extends into the first intermediary section 122 of the trench structure 116. According to this embodiment, the field plate 124 is tapered in the first intermediary section 122 of the trench structure 116. The in situ phases of the etch process used to form the trench structure 116 shown in FIGS. 5A and 5B may be controlled such that the upper section 118 of the trench structure 116 has a relatively wide bottle-like shape which is more conducive to forming a void 500 in the field plate 124 in the upper section 118 during field plate deposition. The void 500 reduces wafer bow/intrinsic mechanical stress. The field plate 124 may be void-free in the first intermediary section 122 of the trench structure 116 which is narrower than the upper section 118 in this embodiment.

The horizontal dashed line in FIG. 5B indicates a target thickness to which the semiconductor substrate 100 is subsequently thinned, e.g., to produce a thin vertical power die (chip) or an SOI die. In one embodiment, the semiconductor substrate 102 is thinned at the back surface 106 (out of view in FIG. 5B) to expose the lower section 120 of the trench structure 116 at the thinned back surface 106 of the substrate 102. The thinned back surface 106 of the substrate 102 may be covered with a dielectric material 108 as shown in FIG. 1, to form an SOI device. As shown in FIG. 5B, the lower section 120 of the trench structure 116 is completely filled by a dielectric material 126 to ensure a vertical dielectric separation between the bottom of the field plate 124 and the back surface 106 of the semiconductor substrate 102 post substrate thinning.

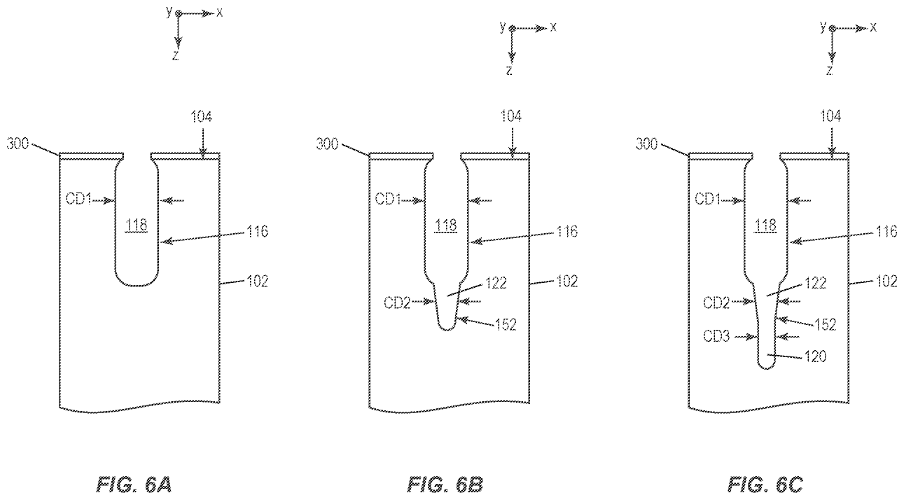

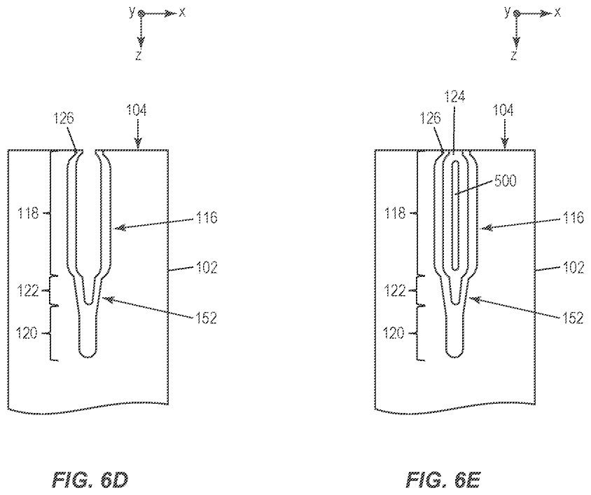

FIGS. 6A through 6E illustrate respective cross-sectional views during in situ phases of an etch process that forms the trench structure 116 shown in FIGS. 5A and 5B.

FIG. 6A shows the semiconductor substrate 102 after the upper section 118 of the trench structure 116 is formed by a first in situ phase of the etch process. The first in situ phase of the etch process may be implemented in accordance with FIGS. 4A through 4D, where the steps illustrated in FIGS. 4B through 4D are repeated as many times as required to yield the bottle-like shape shown in FIG. 6A.

FIG. 6B shows the semiconductor substrate 102 after the first intermediary section 122 of the trench structure 116 is formed by a second in situ phase of the etch process. The second in situ phase of the etch process may be implemented by repeating the steps illustrated in FIGS. 4B through 4D as many times as required to yield the desired profile/geometry for the first intermediary section 122 of the trench structure 116. This may involve a different ramp function and/or number of cycles of RAP-mode etching compared to the RAP-mode and/or steady-state etching used to form the upper section 118 of the trench structure 116, such that the average width/critical dimension CD2 of the first intermediary section 122 is less than the average width/critical dimension CD1 of the upper section 118 and the first intermediary section 122 has tapered sidewalls 152.

FIG. 6C shows the semiconductor substrate 102 after the lower section 120 of the trench structure 116 is formed by a third in situ phase of the etch process. The third in situ phase of the etch process may be implemented by repeating the steps illustrated in FIGS. 4B through 4D as many times as required to yield the desired profile/geometry for the lower section 120 of the trench structure 116. This may involve a different ramp function and/or number of cycles of RAP-mode etching and/or steady-state etching used to form the first intermediary section 122 of the trench structure 116, such that the average width/critical dimension CD3 of the lower section 120 is less than the average width/critical dimension CD2 of the first intermediary section 122.

FIG. 6D shows the semiconductor substrate 102 after lining the sidewalls 152 of the upper section 118 and the first intermediary section 122 and completely filling the lower section 120 of the trench structure 116 with a dielectric material 126. The same or different dielectric material 126 may be used to line the sidewalls 152 of the upper section 118 and the first intermediary section 122 and completely fill the lower section 120 of the trench structure 116. For example, the dielectric material 126 may comprise SiOx and/or SiN and/or HfOx, etc. The dielectric material 126 may be formed by deposition and/or thermal annealing.

Liner pre-treatments may be used such as wet treatments, annealing or plasma treatment to generate interface states. The dielectric trench liner may be partially removed by wet chemistry, recess dry etching, etc. The partial trench liner removal may yield a straight liner surface or a liner surface with a depression that shapes the lower tip/end of the field plate 124 in the bottom part of the trench structure 116.

The dielectric liner thickness effects the dimension of the field plate 124 and should be considered when designing the profile of the trench structure 116. Alternatively, a p/n junction surrounding the silicon layer 110 may be used as the isolation liner.

The trench sidewalls 152 may be doped during any stage of the trench formation process. For example, the trench sidewalls 152 may be doped by plasma doping and annealing, angled sidewall (implantation) doping, doped oxide deposition followed by annealing and out-diffusion, etc.

FIG. 6E shows the semiconductor substrate 102 after forming the field plate 124. The field plate 124 may be made of an electrically conductive material such as doped or undoped polysilicon and/or a metal or metal stack. In FIG. 6E, the width/critical dimension CD1 of the upper section 118 of the trench structure 116 is large enough such that the electrically conductive material does not completely fill the open space in the upper section 118 and which results in an open polysilicon/metal seamline. Accordingly, a void 500 remains in the field plate 124 in the upper section 118 of the trench structure 116. The width/critical dimension CD2 of the first intermediary section 122 of the trench structure 116 may be small enough such that the electrically conductive material completely fills the open space in the first intermediary section 122 and the field plate 124 is void-free in the first intermediary section 122.

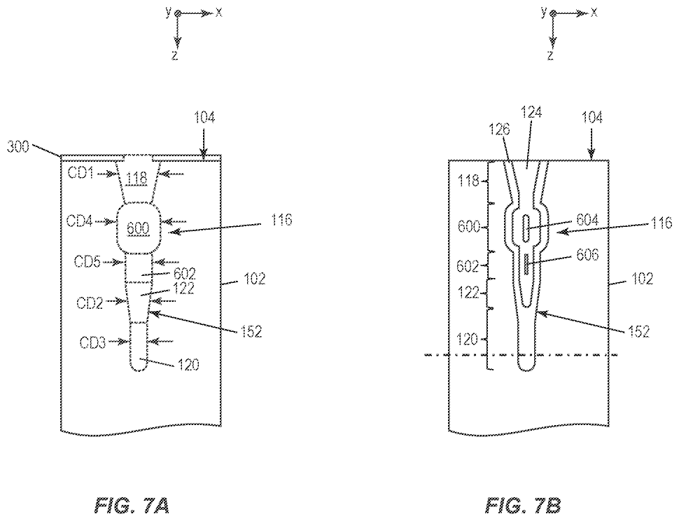

FIGS. 7A and 7B illustrate respective cross-sectional views during different stages of producing the trench structure 116 in one part of the semiconductor substrate 100, according to another embodiment. FIG. 7A shows the trench structure 116 after the lower section 120, the upper section 118, and at least three intermediary sections 122, 600, 602 are etched into the substrate 100 from the front surface 104 but before the field plate 124 and trench dielectric material 126 are formed. FIG. 7B shows the trench structure 116 after the field plate 124 and trench dielectric material 126 are formed.

The in situ phases of the etch process used to form the trench structure 116 shown in FIGS. 7A and 7B are controlled such that the trench structure 116 further includes a second intermediary section 600 between the upper section 118 and the first intermediary section 122 and the second intermediary section 600 has a different geometry than each of the lower section 120, the upper section 118, and the first intermediary section 122. For example, the second intermediary section 600 may have a different shape and/or length (z direction) than each of the lower section 120, the upper section 118, and the first intermediary section 122. Separately or in combination, the second intermediary section 600 may have a different average width/critical dimension than each of the lower section 120, the upper section 118, and the first intermediary section 122 (e.g., CD4>CD1>CD2>CD3).

The in situ phases of the etch process used to form the trench structure 116 shown in FIGS. 7A and 7B may be further controlled such that the trench structure 116 also has a third intermediary section 602 between the second intermediary section 600 and the first intermediary section 122 and the third intermediary section 602 has a different geometry than each of the lower section 120, the upper section 118, the first intermediary section 122, and the second intermediary section 600. For example, the third intermediary section 602 may have a different shape and/or length (z direction) than each of the lower section 120, the upper section 118, the first intermediary section 122, and the second intermediary section 600. Separately or in combination, the third intermediary section 600 may have a different average width/critical dimension than each of the lower section 120, the upper section 118, the first intermediary section 122, and the second intermediary section 600 (e.g., CD5>CD2 and >CD3 and CD5<CD4 and CD1).

The field plate 124 extends into each of the first intermediary section 122, the second intermediary section 600 and the third intermediary section 602 in FIGS. 7A and 7B. The field plate 124 may have a first void 604 in the second intermediary section 600 and/or a second void 606 in the third intermediary section 602. The in situ phases of the etch process used to form the trench structure 116 shown in FIGS. 7A and 7B may be controlled such that the second and/or third intermediary sections 600, 602 of the trench structure 116 have a relatively wide bottle-like shape which is more conducive to forming a respective void 604, 606 in the field plate 124 in one or both of the second and third intermediary sections 600, 602 during field plate deposition. The field plate 124 may be void-free in the first intermediary section 122 of the trench structure 116 which is narrower than the second and third intermediary sections 600, 602 in this embodiment.

In FIGS. 7A and 7B, the first intermediary section 122 adjoins the lower section 120 and has tapered sidewalls 152. The upper section 118 of the trench structure 116 also has tapered sidewalls 152 in FIGS. 7A and 7B.

The horizontal dashed line in FIG. 7B indicates a target thickness to which the semiconductor substrate 100 is subsequently thinned, e.g., to produce a thin vertical power die (chip) or an SOI die. In one embodiment, the semiconductor substrate 102 is thinned at the back surface 106 (out of view in FIG. 7B) to expose the lower section 120 of the trench structure 116 at the thinned back surface 106 of the substrate 102. The thinned back surface 106 of the substrate 102 may be covered with a dielectric material 108 as shown in FIG. 1, to form an SOI device. As shown in FIG. 7B, the lower section 120 of the trench structure 116 is completely filled by a dielectric material 126 to ensure a vertical dielectric separation between the bottom of the field plate 124 and the back surface 106 of the semiconductor substrate 102 post substrate thinning.

The embodiments described herein provide a distinctive deep trench geometry that is realised by an in-situ trench etch process. The in-situ trench etch process may provide multiple trench sections (e.g., 1, 2, 3, etc.) with different geometries, each trench section being defined by CD and length and may be shaped with or without a taper, with or without iso-bowls, etc. The trench structure may be filled by using first a liner (e.g., TEOS (tetraethoxysilane), thermal oxide, SiN, etc.) with a defined thickness, followed by polysilicon deposition which can be doped or undoped. The length of the resulting field plate may be controlled by tuning the corresponding trench segment length and trench segment width. The segment geometry further enables controlled void-engineering to tune the wafer stress level (wafer bow) and wafer fracture strength, where sections with larger CD result in larger void width. The trench section and CD variations may be altered, but the lowermost trench section has the smallest CD and completely filled with a dielectric material without voids.

Although the present disclosure is not so limited, the following numbered examples demonstrate one or more aspects of the disclosure.

Example 1. A semiconductor device, comprising: a semiconductor substrate having a first main surface and a second main surface opposite the first main surface; and a trench structure extending into the semiconductor substrate from the first main surface, wherein the trench structure comprises: an upper section extending into the semiconductor substrate from the first main surface; a lower section at an opposite end of the trench structure as the upper section; a first intermediary section between the upper section and the lower section; a field plate in the upper section and dielectrically insulated from the semiconductor substrate; and a first dielectric material completely filling the lower section, wherein the lower section, the upper section, and the first intermediary section have different geometries and/or different dielectric materials.

Example 2. The semiconductor device of example 1, wherein the first intermediary section adjoins the lower section and has tapered sidewalls, and wherein an average width of the lower section is less than an average width of the first intermediary section.

Example 3. The semiconductor device of example 2, wherein the average width of the upper section is greater than the average width of the first intermediary section.

Example 4. The semiconductor device of any of examples 1 through 3, wherein the first intermediary section has tapered sidewalls.

Example 5. The semiconductor device of any of examples 1 through 4, wherein the field plate extends into the first intermediary section.

Example 6. The semiconductor device of example 5, wherein the field plate is tapered in the first intermediary section.

Example 7. The semiconductor device of example 6, wherein the field plate has a void in the upper section, and wherein the field plate is void-free in the first intermediary section.

Example 8. The semiconductor device of any of examples 1 through 7, wherein the trench structure further comprises a second intermediary section between the upper section and the first intermediary section, and wherein the second intermediary section has a different geometry than each of the lower section, the upper section, and the first intermediary section.

Example 9. The semiconductor device of example 8, wherein the trench structure further comprises a third intermediary section between the second intermediary section and the first intermediary section, and wherein the third intermediary section has a different geometry than each of the lower section, the upper section, the first intermediary section, and the second intermediary section.

Example 10. The semiconductor device of example 9, wherein the field plate extends into each of the first intermediary section, the second intermediary section and the third intermediary section.

Example 11. The semiconductor device of example 10, wherein the field plate has a void in the second intermediary section and/or the third intermediary section and is void-free in the first intermediary section.

Example 12. The semiconductor device of example 10 or 11, wherein the first intermediary section adjoins the lower section and has tapered sidewalls.

Example 13. The semiconductor device of any of examples 1 through 12, further comprising: a second dielectric material covering the second main surface, wherein the trench structure extends through the semiconductor substrate from the first main surface to the second main surface such that the lower section adjoins the second dielectric material.

Example 14. A method of producing a semiconductor device, the method comprising: forming, by an etch process, a trench structure that extends into a semiconductor substrate from a first main surface of the semiconductor substrate; controlling a plurality of in situ phases of the etch process such that the trench structure has a plurality of sections with different geometries, including an upper section that extends into the semiconductor substrate from the first main surface, a first intermediary section below the upper section, and a lower section below the first intermediary section and at an opposite end of the trench structure as the upper section; forming a first dielectric material that completely fills the lower section; and forming a field plate in the upper section and that is dielectrically insulated from the semiconductor substrate.

Example 15. The method of example 14, further comprising: after forming the trench structure, thinning a second main surface of the semiconductor substrate opposite the first main surface to expose the lower section at the second main surface; and after the thinning, covering the second main surface with a second dielectric material.

Example 16. The method of example 14 or 15, wherein the first intermediary section adjoins the lower section, wherein an in situ phase of the etch process that forms the first intermediary section is controlled such that the first intermediary section has tapered sidewalls, and wherein an in situ phase of the etch process that forms the lower section is controlled such that an average width of the lower section is less than an average width of the first intermediary section.

Example 17. The method of example 14, wherein an in situ phase of the etch process that forms the first intermediary section is controlled such that the first intermediary section has tapered sidewalls.

Example 18. The method of any of examples 14 through 17, wherein the field plate extends into the first intermediary section.

Example 19. The method of example 18, wherein an in situ phase of the etch process that forms the first intermediary section is controlled such that the first intermediary section has tapered sidewalls, and wherein the field plate is tapered in the first intermediary section.

Example 20. The method of any of examples 14 through 19, wherein the field plate has a void in the upper section, and wherein the field plate is void-free in the first intermediary section.

Example 21. The method of any of examples 14 through 20, wherein the plurality of in situ phases of the etch process is controlled such that the trench structure further comprises a second intermediary section between the upper section and the first intermediary section and the second intermediary section has a different geometry than each of the lower section, the upper section, and the first intermediary section.

Example 22. The method of example 21, wherein the plurality of in situ phases of the etch process is controlled such that the trench structure further comprises a third intermediary section between the second intermediary section and the first intermediary section and the third intermediary section has a different geometry than each of the lower section, the upper section, the first intermediary section, and the second intermediary section.

Example 23. The method of example 22, wherein the field plate extends into each of the first intermediary section, the second intermediary section and the third intermediary section.

Example 24. The method of example 22 or 23, wherein the field plate has a void in the second intermediary section and/or the third intermediary section and is void-free in the first intermediary section.

Example 25. The method of any of examples 22 through 24, wherein the first intermediary section adjoins the lower section, and wherein an in situ phase of the etch process that forms the first intermediary section is controlled such that the first intermediary section has tapered sidewalls.

Example 26. The method of any of examples 14 through 25, wherein a same mask remains on the first main surface of the semiconductor substrate during each in situ phase of the etch process.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor substrate having a first main surface and a second main surface opposite the first main surface; and
a trench structure extending into the semiconductor substrate from the first main surface,
wherein the trench structure comprises:
an upper section extending into the semiconductor substrate from the first main surface;
a lower section at an opposite end of the trench structure as the upper section;
a first intermediary section between the upper section and the lower section;
a field plate in the upper section and dielectrically insulated from the semiconductor substrate; and
a first dielectric material completely filling the lower section,
wherein the lower section, the upper section, and the first intermediary section have different geometries and/or different dielectric materials.

2. The semiconductor device of claim 1, wherein the first intermediary section adjoins the lower section and has tapered sidewalls, and wherein an average width of the lower section is less than an average width of the first intermediary section.

3. The semiconductor device of claim 2, wherein the average width of the upper section is greater than the average width of the first intermediary section.

4. The semiconductor device of claim 1, wherein the first intermediary section has tapered sidewalls.

5. The semiconductor device of claim 1, wherein the field plate extends into the first intermediary section.

6. The semiconductor device of claim 5, wherein the field plate has a void in the upper section, and wherein the field plate is void-free in the first intermediary section.

7. The semiconductor device of claim 1, wherein the trench structure further comprises a second intermediary section between the upper section and the first intermediary section, and wherein the second intermediary section has a different geometry than each of the lower section, the upper section, and the first intermediary section.

8. The semiconductor device of claim 7, wherein the trench structure further comprises a third intermediary section between the second intermediary section and the first intermediary section, and wherein the third intermediary section has a different geometry than each of the lower section, the upper section, the first intermediary section, and the second intermediary section.

9. The semiconductor device of claim 8, wherein the field plate extends into each of the first intermediary section, the second intermediary section and the third intermediary section.

10. The semiconductor device of claim 9, wherein the field plate has a void in the second intermediary section and/or the third intermediary section and is void-free in the first intermediary section.

11. The semiconductor device of claim 9, wherein the first intermediary section adjoins the lower section and has tapered sidewalls.

12. The semiconductor device of claim 1, further comprising:
a second dielectric material covering the second main surface,
wherein the trench structure extends through the semiconductor substrate from the first main surface to the second main surface such that the lower section adjoins the second dielectric material.

13. A method of producing a semiconductor device, the method comprising:
forming, by an etch process, a trench structure that extends into a semiconductor substrate from a first main surface of the semiconductor substrate;
controlling a plurality of in situ phases of the etch process such that the trench structure has a plurality of sections with different geometries, including an upper section that extends into the semiconductor substrate from the first main surface, a first intermediary section below the upper section, and a lower section below the first intermediary section and at an opposite end of the trench structure as the upper section;
forming a first dielectric material that completely fills the lower section; and
forming a field plate in the upper section and that is dielectrically insulated from the semiconductor substrate.

14. The method of claim 13, further comprising:
after forming the trench structure, thinning a second main surface of the semiconductor substrate opposite the first main surface to expose the lower section at the second main surface; and
after the thinning, covering the second main surface with a second dielectric material.

15. The method of claim 13, wherein the first intermediary section adjoins the lower section, wherein an in situ phase of the etch process that forms the first intermediary section is controlled such that the first intermediary section has tapered sidewalls, and wherein an in situ phase of the etch process that forms the lower section is controlled such that an average width of the lower section is less than an average width of the first intermediary section.

16. The method of claim 13, wherein an in situ phase of the etch process that forms the first intermediary section is controlled such that the first intermediary section has tapered sidewalls.

17. The method of claim 13, wherein the field plate extends into the first intermediary section.

18. The method of claim 17, wherein an in situ phase of the etch process that forms the first intermediary section is controlled such that the first intermediary section has tapered sidewalls, and wherein the field plate is tapered in the first intermediary section.

19. The method of claim 13, wherein the field plate has a void in the upper section, and wherein the field plate is void-free in the first intermediary section.

20. The method of claim 13, wherein the plurality of in situ phases of the etch process is controlled such that the trench structure further comprises a second intermediary section between the upper section and the first intermediary section and the second intermediary section has a different geometry than each of the lower section, the upper section, and the first intermediary section.

21. The method of claim 20, wherein the plurality of in situ phases of the etch process is controlled such that the trench structure further comprises a third intermediary section between the second intermediary section and the first intermediary section and the third intermediary section has a different geometry than each of the lower section, the upper section, the first intermediary section, and the second intermediary section.

22. The method of claim 21, wherein the field plate extends into each of the first intermediary section, the second intermediary section and the third intermediary section.

23. The method of claim 21, wherein the field plate has a void in the second intermediary section and/or the third intermediary section and is void-free in the first intermediary section.

24. The method of claim 21, wherein the first intermediary section adjoins the lower section, and wherein an in situ phase of the etch process that forms the first intermediary section is controlled such that the first intermediary section has tapered sidewalls.

25. The method of claim 13, wherein a same mask remains on the first main surface of the semiconductor substrate during each in situ phase of the etch process.
